(19) United States
(12) Patent Application Publication
(10) Pub. No.: US 2001/0015465 A1
(43) Pub. Date: Aug. 23, 2001

(54) Method for forming a transistor for a semiconductior device

(76) Inventors: Jeong Kug Lee, Seoul (KR); Yeon Cheol Heo, Seoul (KR)

Correspondence Address: Pillsbury Winthrop LLP, Intellectual Property Group, Ninth Floor, East Tower, 1100 New York Avenue, NW., Washington, DC, 20005-3918, US

(21) Appl. No.: 09/751,845

(22) Filed: Jan. 2, 2001

(30) Foreign Application Priority Data
Dec. 30, 1999 (KR) 1999-67047

(51) Int. Cl. H01L 21/336; H01L 29/76; H01L 29/94; H01L 31/062; H01L 31/113; H01L 31/119

(52) U.S. Cl. 257/394; 438/284

(57) ABSTRACT

The present invention discloses a method for forming transistors for semiconductor devices that can prevent degradation of device properties by interrupting a current path from a drain junction region to a source junction region with an insulating channel barrier structure. The method includes the steps of: forming a device isolating film for defining an active region, and simultaneously forming a channel barrier film at the lower portion of a gate electrode formation region; partially etching the upper portion of the channel barrier film to form a recess; filling the recess above the upper portion of the channel barrier film with silicon; patterning a gate oxide film and a gate electrode on the stacked structure of the channel barrier film and silicon; and forming the transistor by forming source/drain junction regions in the exposed semiconductor substrate. The channel barrier structure, by limiting the depth of the channel region, improves the punch through resistance, improves the reliability, and allows increased levels of integration in the resulting semiconductor device.

### BACKGROUND OF THE INVENTION

1. Field of the Invention

The present invention relates to a method for forming a transistor for a semiconductor device and, in particular, to an improved method for forming a transistor that which can achieve high degrees of integration of the semiconductor device by preventing a punch through phenomenon from occurring between source and drain regions due to reduced gate electrode spacing.

2. Description of the Background Art

In order to produce a highly integrated semiconductor device, it is essential to miniaturize the incorporated transistors. However, as the size of the transistor is reduced, the transistors become more prone to punch through phenomenon.

In particular, as the semiconductor device becomes more highly integrated, the gate electrode gets smaller, which allows the punch through phenomenon to occur between adjacent source and drain junction regions.

In order to minimize or suppress the punch through phenomenon, one method for restricting growth of a depletion region and improving the punch through resistance of the source/drain junction regions relies on increasing the dopant concentration in the field region and the channel region to adjust the threshold voltage of the transistor.

FIG. 1 is a cross-sectional diagram illustrating the structure produced by a conventional method for forming a transistor for a semiconductor device.

Firstly, a trench type device isolating film 53 for defining an active region is formed on a semiconductor substrate 51. A gate oxide film 55 is then formed on the semiconductor substrate 51.

A gate electrode 57 is then formed on the gate oxide film 55.

Thereafter, insulating film spacers 59 are formed at the sidewalls of the gate electrode 57, and impurity junction regions of a lightly doped drain (LDD) structure, namely source/drain regions 61a and 61b are formed in substrate 51. These structures are formed by sequentially performing deposition and etchback processes to form the spacers at the sidewalls of the gate electrode 57 and two ion implantation processes to form the highly-doped and lightly-doped impurity regions of the LDD structures.

As illustrated in FIG. 1, a depletion region extending from the curvature portion of the drain junction region 61b is very weakened due to a large amount of field 63. When the drain depletion region contacts the source depletion region of the source junction region 61a, an unwanted current path 65 is generated between the source and drain, instead of forming a current path through a channel. This current path 65 is less subject to control by the gate electrode 57, and as a result, it remarkably affects the operation of the device, decreasing both the performance and life span of the device.

Moreover, the increased dopant concentration between the source junction region 61a and the drain junction region 61b increases the threshold voltage and junction capacitance. Accordingly, an additional ion implantation process is required to increase the dopant concentration of the region having a relatively small dopant concentration.

Another approach uses a method for preventing the source depletion region from contacting the drain depletion region by forming shallow source/drain junction regions. However, when metal contacts are subsequently formed on the source/drain junction regions in order to form the necessary electrical connections, the junction regions may be damaged by excessive contact etching. Further, the reduced junction depth increases the resistance increases, thereby decreasing the saturated current.

Further, the conventional method requires a mask operation and an oxidation or ion implantation process in order to form transistors having different threshold voltages in one chip. Accordingly, at least three mask operations and three ion implantation processes would be required to form three transistors having different threshold voltages.

As described above, the conventional method for forming the transistor for a semiconductor device tends to increase the threshold voltage and junction capacitance. These problems are increased for more highly integrated semiconductor devices, thereby degrading the device operational properties. As a result, the reliability of the semiconductor device is reduced, and the desired levels of integration cannot be achieved.

### SUMMARY OF THE INVENTION

Accordingly, an object of the present invention is to provide a method for forming a transistor for a semiconductor device which improves the electrical properties and reliability of the resulting semiconductor device and is suitable for high levels of integration. The present method involves forming a device isolating film at the lower portion of a gate electrode of the transistor, thereby preventing impurity diffusion between source/drain junction regions, and suppressing formation of an unwanted current path. With this method the resulting device properties are not degraded by increased threshold voltage and junction capacitance even in highly integrated semiconductor devices.

In order to achieve the above-described object of the present invention, there is provided a method for forming a transistor of a semiconductor device, including the steps of: forming a trench type device isolating film for defining an active region and simultaneously forming a trench type channel barrier film at the lower portion of a gate electrode formation region; partially etching the upper portion of the channel barrier film; planarizing the channel barrier film silicon to form a stacked structure with silicon above the channel barrier film; patterning a gate oxide film and a gate electrode on the stacked structure of the channel barrier film and silicon; and forming the transistor by forming source/drain junction regions in the exposed active region of the semiconductor substrate.

In addition, there is provided a method for forming a transistor for a semiconductor device, including the steps of: forming a device isolating film for defining an active region of a semiconductor substrate, and simultaneously forming a trench type channel barrier film; forming an amorphous silicon layer, by forming and re-crystallizing a first amorphous silicon layer over the entire structure, and stacking a second amorphous silicon layer of a substantially equal thickness on the first amorphous silicon layer; removing the amorphous silicon layers on the active region, and simultaneously patterning the amorphous silicon layers on a non-active region to form amorphous silicon patterns for high voltage and low voltage; crystallizing the amorphous silicon pattern intended for the low voltage circuit using a laser re-growth method and a thermal treatment; forming a gate oxide film and a polysilicon film for a gate electrode over the entire structure; and forming source/drain junction regions by ion-implanting an impurity into the semiconductor substrate.

The principle for achieving the object of the prevent invention will now be explained.

When the device isolating film is formed, the trench type channel barrier film is formed at the lower portion of the gate electrode. The channel barrier film is etched to remove a predetermined thickness, and then filled with a conductive silicon layer for planarization. The gate insulating film, the gate electrode and the impurity junction regions are then formed in subsequent process steps. Accordingly, no unwanted current path is formed between the drain junction region and the source junction region, thereby preventing malfunction of the resulting device and improving the electrical properties and reliability thereof.

### BRIEF DESCRIPTION OF THE DRAWINGS

The present invention will better understood with reference to the accompanying figures which are given only by way of illustration and thus should not be considered to unnecessarily limit the present invention.

FIG. 1 is a cross-sectional diagram illustrating the structure produced using a conventional method for forming a transistor for a semiconductor device;

FIGS. 2A through 2F are cross-sectional diagrams illustrating sequential steps of a method for forming a transistor of a semiconductor device in accordance with a first embodiment of the present invention; and

FIGS. 3A through 3I are cross-sectional diagrams illustrating sequential steps of a method for forming a transistor of a semiconductor device in accordance with a second embodiment of the present invention.

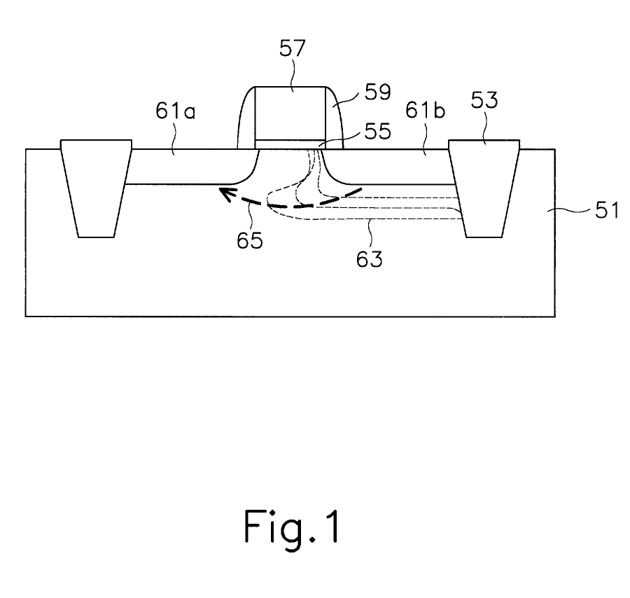

### DETAILED DESCRIPTION OF THE PREFERRED EMBODIMENTS

A method for forming a transistor for a semiconductor device in accordance with the present invention will now be described in detail with reference to the accompanying drawings.

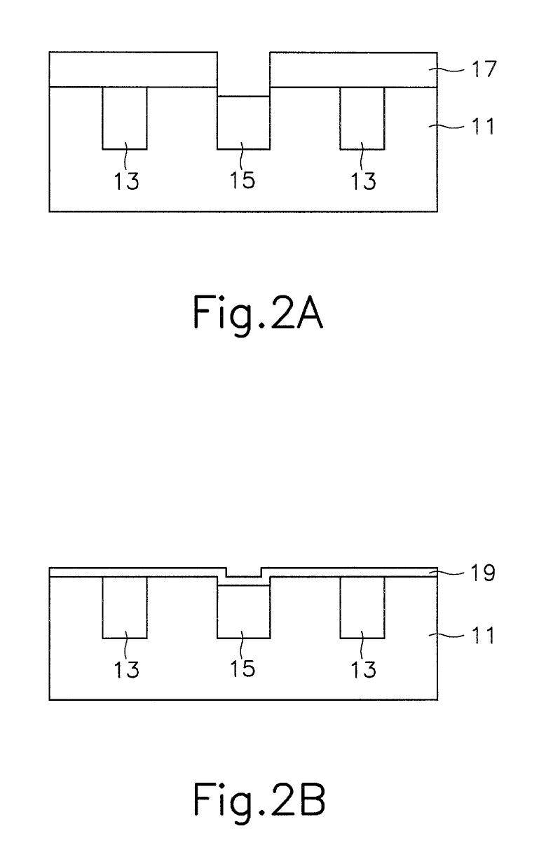

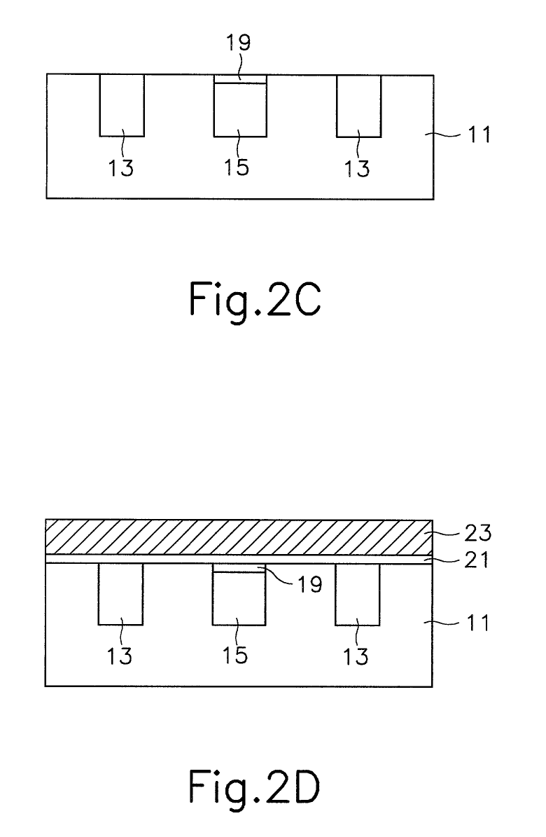

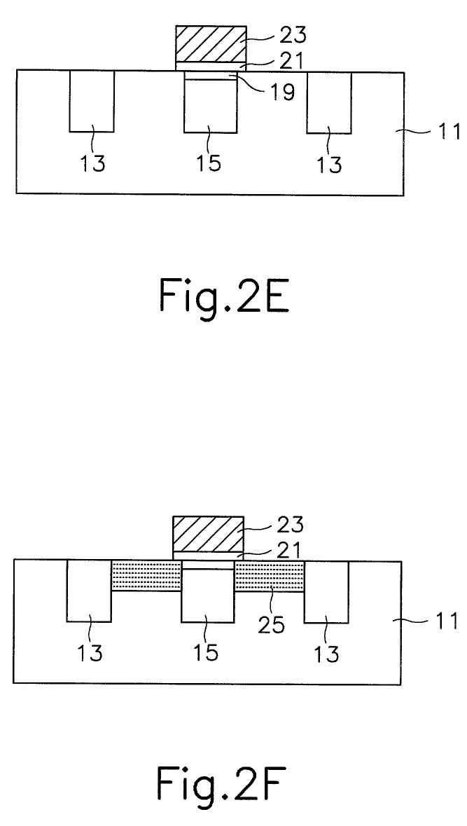

As illustrated in FIG. 2A, a trench type device isolating films 13 for defining an active region are is formed on a semiconductor substrate 11. Here, a channel barrier film 15, having a structure similar to that of the trench type device isolating film 13, is formed in that portion of the active region above which the gate electrode will subsequently be formed.

A photoresist film pattern 17 exposing the channel barrier film 15 is formed on the semiconductor substrate 11. The channel barrier film 15 is then etched to remove a predetermined thickness, by employing the photoresist film pattern 17 as a mask. The photoresist film pattern 17 is formed according to conventional exposure and development processes using a gate electrode mask.

Referring to FIG. 2B, the photoresist film pattern 17 is removed, and a single crystal silicon layer 19 is formed over the entire structure at a thickness of 100 to 500Å. Here, a portion of the single crystal silicon layer 19 is disposed on the active region below the intended location of the gate electrode (not shown), and has a sufficient thickness so that the channel region of the transistor can be later formed. In addition, the single crystal silicon layer 19 is preferably formed using an epitaxial growth method.

As shown in FIG. 2C, the majority of the single crystal silicon layer 19 is removed by an etch back or a chemical mechanical polishing (CMP) process. The remaining portion of the single crystal silicon layer 19 is located above the channel barrier film 15.

As depicted in FIG. 2D, a silicon oxide film 21, which is an insulating film for the gate electrode, and a polysilicon film 23, which is a conductive film for the gate electrode, are sequentially formed over the entire structure.

As illustrated in FIG. 2E, a gate electrode having the stacked structure of the silicon oxide film 21 and the polysilicon film 23 is formed in accordance with a photolithography process using a gate electrode mask (not shown) as an etching mask. The gate electrode is also formed above the stacked structure of the single crystal silicon layer 19 and the channel barrier film 15.

As shown in FIG. 2F, an impurity junction region 25 is then formed by ion-implanting an impurity into the active region of the semiconductor substrate 11.

At this time, the impurity junction region 25 may have an LDD structure according to a process for forming an insulating film spacer (not shown) at the side walls of the gate electrode.

In accordance with the first embodiment of the present invention, an amorphous silicon or polysilicon layer of 15-2000Å may be grown and re-crystallized as an alternative to the single crystal silicon layer 19 described above. When the amorphous silicon or polysilicon is used, the etching process can be carried out either before or after the re-crystallization process has been conducted.

In addition, the natural oxide film formed on the surface either before or after the re-crystallization of the amorphous silicon or polysilicon may be utilized as a diffusion barrier film in a succeeding process.

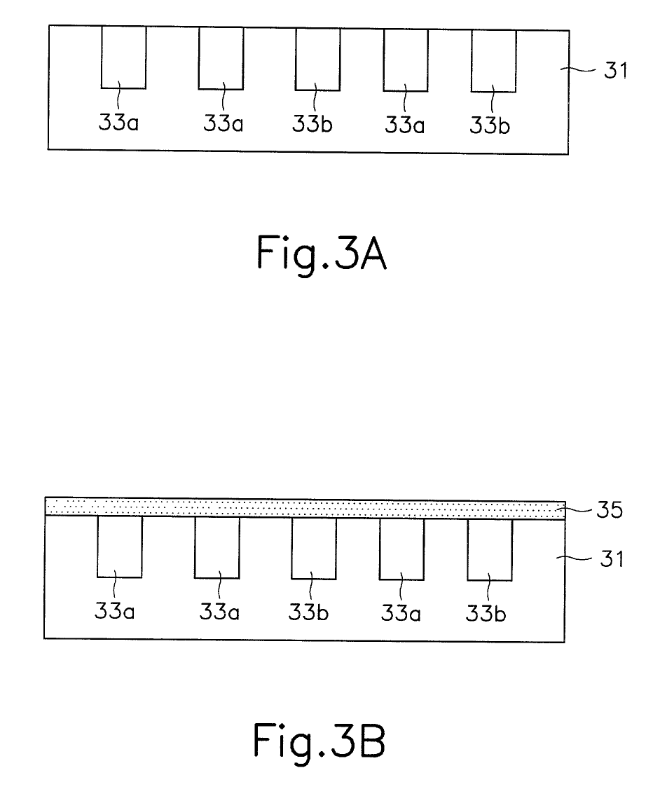

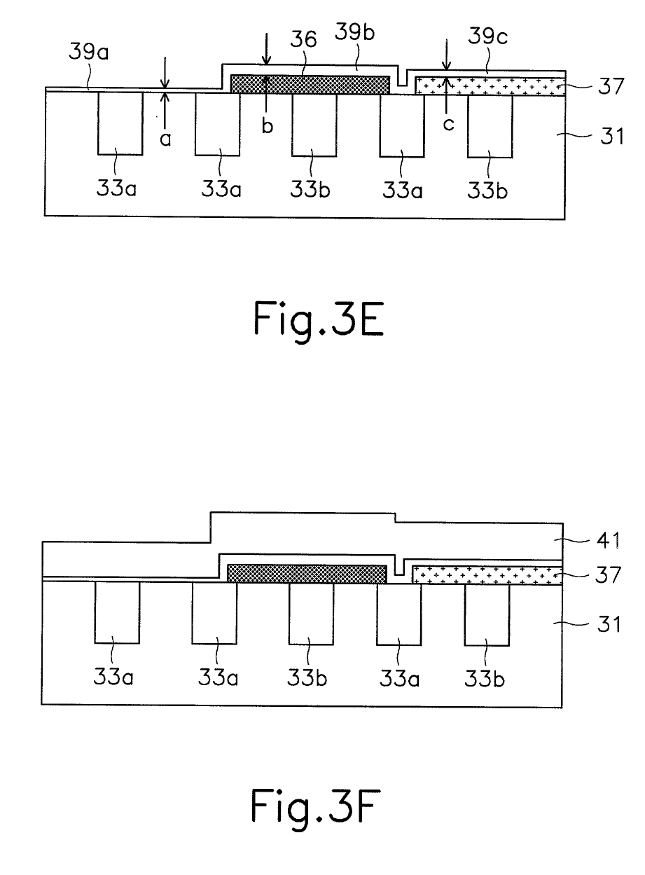

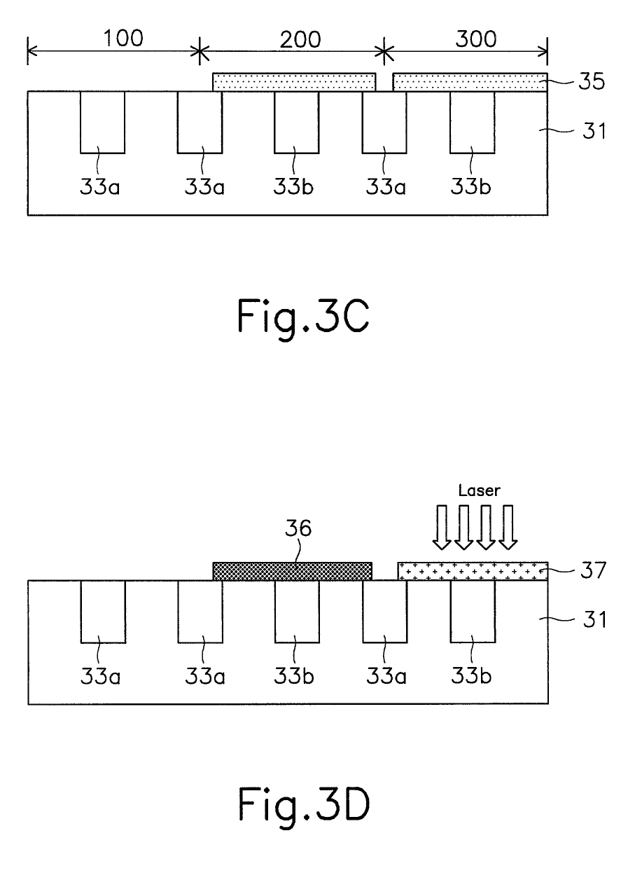

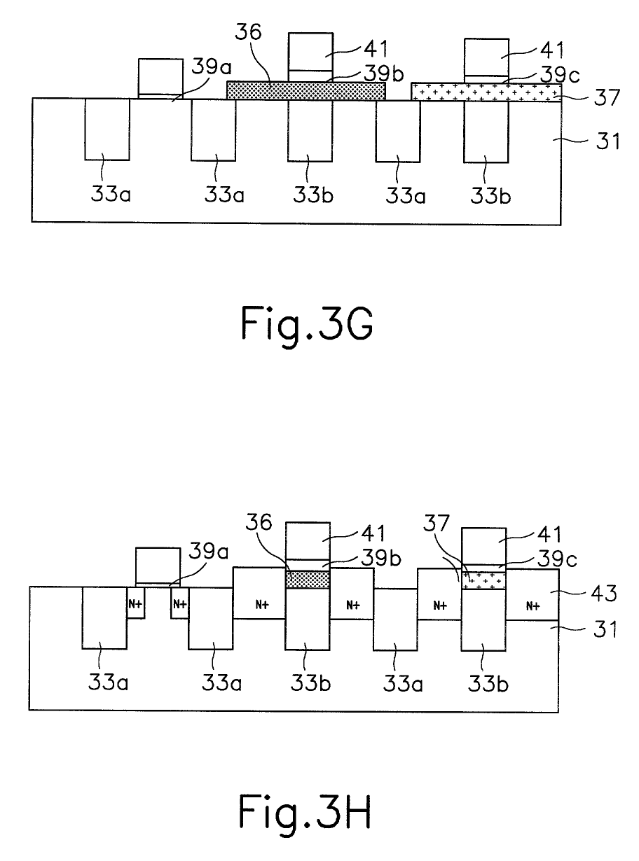

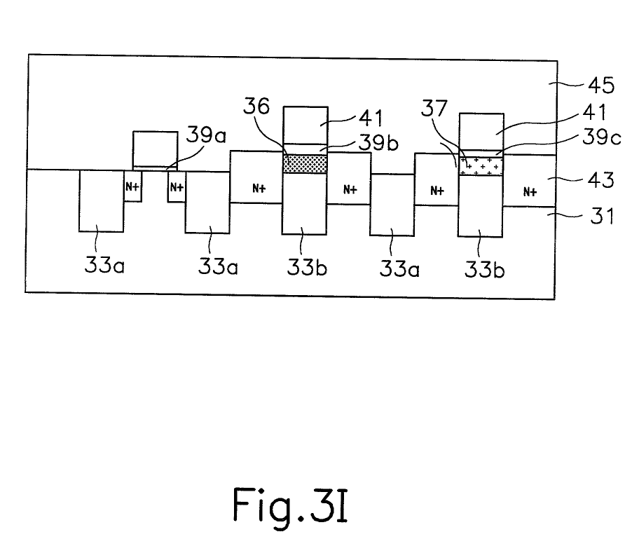

FIGS. 3A through 3I are cross-sectional diagrams illustrating sequential steps of the method for forming the transistor of the semiconductor device in accordance with a second embodiment of the present invention, in a state where three gate oxide films, each having a different thickness are used in a flash memory. A method in which the second gate oxide 39b is the thickest and is used for high voltage operation which in the driving circuit region, the third gate oxide film 39c is used for low voltage operation, and the first gate oxide film 39a is the thinnest and is used as the tunnel oxide film in the cell region will now be described.

As illustrated in FIG. 3A, trench type device isolating films 33a for defining active regions and trench type channel barrier films 33b are formed in a semiconductor substrate 31. The channel barrier films 33b are formed in the region of the semiconductor substrate 31 where a gate electrode (not shown) will be formed.

Referring to FIG. 3B, a first amorphous silicon layer having a thickness of 15 to 2000Å is formed and re-crystallized over the resulting structure so that a channel of the transistor can be formed. A second amorphous silicon layer having substantially equal thickness to the first amorphous silicon layer is formed thereon, thereby forming an amorphous silicon layer 35 having a stacked structure.

As shown in FIGS. 3C and 3D, the amorphous silicon layer 35 in the active region is removed, and at the same time the amorphous silicon layer 35 in the non-active region is patterned to form an amorphous silicon layer pattern 36 for high voltage operation and an amorphous silicon layer pattern 37 for low voltage operation.

The amorphous silicon layer pattern 37 for the low voltage is crystallized preferably using a laser re-growth method and a thermal treatment.

Here, reference numeral 100 denotes a region where the tunnel oxide film will be formed, 200 denotes a region where a driving circuit for high voltage operation will be provided, and 300 denotes a region where a transistor for low voltage operation will be provided.

As depicted in FIG. 3E, a gate oxide film 39 is formed over the entire structure. Here, the first gate oxide film 39a is formed with a thickness ‘a’ in the region 100, the second gate oxide film 39b is formed with a thickness ‘b’ in the region 200, and the third gate oxide film 39c is formed with a thickness ‘c’ in the region 300.

In the present invention, the thicknesses, ‘a’, ‘b’ and ‘c’, representing gate oxide films 39a, 39b, 39c, satisfy the relation ‘b>c>a’. That is, the silicon layers on which the gate oxide films are grown have a different material properties, and thus exhibit different oxide growth rates under the same oxidation conditions.

Referring to FIGS. 3F and 3G, a polysilicon film 41 that will provide a gate electrode is formed over the resulting structure. The polysilicon film 41 and the gate oxide film 39 are then etched according to conventional photolithography and etch processes using a gate electrode mask (not shown), to form a gate electrode in each of the three regions.

As illustrated in FIG. 3H, source/drain junction regions are formed by ion-implanting impurity ions into the semiconductor substrate 31, thereby forming a transistor.

In the case of the amorphous silicon layer patterns 36 and 37, for the high voltage and low voltage operations respectively, form a portion of the impurity junction regions of the source/drain junction regions.

As shown in FIG. 3I, an interlayer insulating film 45 for planarizing the whole surface of the resultant structure is formed.

In accordance with the second embodiment of the present invention, a polysilicon layer may replace the amorphous silicon layer. In addition, the re-crystallization process may be omitted entirely by using the single crystal silicon, instead of the amorphous silicon or polysilicon.

A natural oxide film may be employed as a diffusion barrier film, by omitting any process that would tend to remove the natural oxide film before and/or after the re-crystallization.

As discussed earlier, in accordance with the present invention, the channel region is formed at the lower portion of the gate electrode by using silicon from either the original substrate or from the deposited film, and the device isolating film is formed at the lower portion of the channel region, thereby separating the lower regions of source/drain junction regions. As a result, a current path cannot form between the lower portion of the drain region and the lower portion of the source region. Thus the operational properties of the semiconductor device are improved, the electrical properties and reliability of the semiconductor device are improved, and high levels of integration can be successfully achieved.

As the present invention may be embodied in several forms without departing from the spirit or essential characteristics thereof, it should also be understood that the above-described embodiments are not necessarily limited to the specific details of the foregoing description, unless otherwise specified. The present invention should, therefore, be construed broadly within the spirit and scope of the appended claims, and an encompassing all changes and modifications that fall within the metes and bounds of the claims, or equivalents of such metes and bounds are therefore intended to be embraced by the appended claims.

What is claimed is:

1. A method for forming a transistor for a semiconductor device, comprising the steps of:
forming a trench type device isolating film for defining an active region on the semiconductor substrate, and simultaneously forming a trench type channel barrier film in the active region;
removing an upper portion of the channel barrier film;
planarizing the channel barrier film with a semiconductor substrate, by replacing upper portion of the channel barrier film with a silicon to form a stacked structure;
forming a gate oxide and a gate electrode on the stacked structure; and
forming source/drain junction regions in the active region on opposite sides of the gate electrode.

2. The method according to claim 1, wherein the silicon is amorphous silicon or polysilicon.

3. The method according to claim 1 or 2, wherein the silicon has a thickness of 15 to 2000Å.

4. The method according to claim 1, wherein the silicon is single crystal silicon using an epitaxial method.

5. The method according to claim 2, wherein the silicon is further subjected to a re-crystallization process.

6. The method according to claim 5, wherein a natural oxide film is allowed to form on the silicon, the natural oxide film being employed as a diffusion barrier film during a subsequent process.

7. A method for forming a transistor of a semiconductor device, comprising the steps of:
forming a device isolating film, the device isolating film defining an active region, a high voltage region, a low voltage region, a trench type channel barrier film, and an isolation region on a semiconductor substrate;
forming a silicon layer;
forming a silicon pattern wherein the silicon layer is removed from the active region, thereby exposing the semiconductor substrate, a first portion of the silicon layer remains in the high voltage region, and a second portion of the silicon layer remains in the low voltage region;
forming a gate oxide film and a polysilicon film over the active region, the low voltage region, and the high voltage region;
etching the gate oxide film and the polysilicon film to form gate structures in the active region, the low voltage region, and the high voltage region; and
implanting impurity ions using the gate structures as an implant mask to form source/drain junction regions in the active region, the low voltage region, and the high voltage region.

8. The method according to claim 7, wherein the channel barrier film is formed in the regions of the semiconductor substrate above which gate structure will be formed.

9. The method according to claim 7, wherein the step of forming the silicon layer further comprises
forming a first amorphous silicon film of predetermined thickness;
re-crystallizing the first amorphous silicon film;
forming a second amorphous silicon film of substantially the predetermined thickness, the stacked structure of the first and second silicon films comprising the silicon layer
and further comprises the step of
crystallizing the second portion of the silicon layer.

10. The method according to claim 9, wherein the first amorphous silicon film has a thickness of between about 15 and 2000Å.

11. The method according to claim 7, wherein a portion of the gate oxide film formed on the first portion of the silicon layer is thicker than a portion of the gate oxide film formed on the second portion of the silicon layer, and further wherein
the portion of the gate oxide film formed on the second portion of the silicon layer is thicker than a portion of the gate oxide film formed on the semiconductor substrate in the active region.

12. The method according to claim 7, wherein the silicon layer comprises single crystal silicon or polysilicon.

13. The method according to claim 7, further comprising the step of
forming a natural oxide film on exposed silicon, the natural oxide film being utilized as a diffusion barrier during a subsequent process.

14. A semiconductor device having a cell region, a low voltage region, and a high voltage region formed on a semiconductor substrate comprising
a device isolating film, the device isolating film defining a cell region, a high voltage region, a low voltage region, a trench type channel barrier film, and an isolation region on a semiconductor substrate;
the high voltage region further comprising a trench type channel barrier film formed in the semiconductor substrate, a first silicon pattern formed on the semiconductor substrate and over the trench type channel barrier film, a gate structure comprising a stacked structure of a gate oxide and a gate electrode formed on the first silicon pattern, and source/drain junction regions formed on opposite sides of the gate structure;
the low voltage region further comprising a trench type channel barrier film formed in the semiconductor substrate, a second silicon pattern formed on the semiconductor substrate and over the trench type channel barrier film, a gate structure comprising a stacked structure of a gate oxide and a gate electrode formed on the second silicon pattern and source/drain junction regions formed on opposite sides of the gate structure; and
the cell region further comprising a gate structure comprising a stacked structure of a gate oxide and a gate electrode formed on the semiconductor substrate and source/drain junction regions formed on opposite sides of the gate structure.

15. A semiconductor device having a cell region formed on a semiconductor substrate comprising
a device isolating film, the device isolating film defining the cell region, a trench type channel barrier film, and an isolation region on a semiconductor substrate;
the cell region further comprising
the trench type channel barrier film formed in the semiconductor substrate and below the surface of the surrounding semiconductor substrate, forming a recess of predetermined depth;
a silicon plug formed above the trench type channel barrier film and filling the recess;
a gate structure comprising a stacked structure of a gate oxide and a gate electrode formed above the silicon plug; and
source/drain junction regions formed on opposite sides of the gate structure.
